(19) United States
(12) Patent Application Publication
(10) Pub. No.: US 2011/0169579 A1
(43) Pub. Date: Jul. 14, 2011

(54) METHOD AND APPARATUS FOR INCREASING DISTRIBUTION OF JITTER WITHIN A RANDOM NUMBER GENERATOR

(76) Inventor: James Dodrill, Dripping Springs, TX (US)

(21) Appl. No.: 12/957,290

(22) Filed: Nov. 30, 2010

Related U.S. Application Data
(60) Provisional application No. 61/293,405, filed on Jan. 8, 2010.

(51) Int. Cl. H03K 3/03

(52) U.S. Cl. 331/46; 331/57

(57) ABSTRACT

A random number generator comprises a first high frequency (HF) oscillator, a second low frequency (LF) oscillator, a delay buffer, a multiplexer, and a sampling circuit. The HF oscillator generates a high frequency oscillating signal. The LF oscillator generates a low frequency oscillating signal. The multiplexer selects from the LF oscillating signal and one or more delayed version of the LF oscillating signal to generate a third oscillating signal. The third oscillating signal is then used to sample the HF oscillating signal to output a random bit stream. In one preferred embodiment, the random bit stream is feedback to the multiplexer to make randomized selection. As a result, the original jitter distribution of the LF oscillating signal is increased to a larger jitter distribution of the third oscillating signal to increase the random behavior of the output bit stream.

### CROSS REFERENCE TO RELATED APPLICATIONS

This application claims priority under 35 U.S.C. §119 from U.S. Provisional Application No. 61/293,405, entitled “Method for Increasing the Distribution of Jitter within a Random Number Generator,” filed on Jan. 8, 2010, the subject matter of which is incorporated herein by reference.

### TECHNICAL FIELD

The present invention relates generally to random number generator, and, more particularly, to increasing distribution of jitter within a random number generator.

### BACKGROUND

A random number generator is a physical or computational device designed to generate a sequence of numbers or symbols that lack any pattern. Random number generators are often used in applications such as gambling, statistical sampling, computer simulation, cryptography, completely randomized design, and other areas where producing an unpredictable result is desirable. In general, when unpredictability is paramount, such as in security-related applications, hardware generators are generally preferred over pseudo-random algorithms. A hardware random number generator is based on measurements on some physical phenomenon that is expected to be truly random. For example, true random sources include radioactive decay, thermal noise, shot noise, avalanche noise in Zener diodes, and radio noise. If a stochastic source of randomness can be sufficiently isolated from all deterministic influences, then a truly random number generator can be realized. In complementary metal-oxide-semiconductor (CMOS) technology, one common random number generating technique involves the use of timing jitter found in ring oscillators as a source of randomness. Timing jitter is a stochastic phenomenon caused by thermal noise present in the transistors of a ring oscillator. Because thermal noise is a true random source, two or more oscillators can be combined to produce a sequence of true random bit stream.

FIG. 1 (Prior Art) illustrates a conventional random number generator (RNG) 10. RNG 10 comprises a high frequency (HF) oscillator 11, a low frequency (LF) oscillator 12, and a D-type flip-flop (DFF) 13. HF oscillator 11 generates a high frequency oscillating signal 14, which provides an input signal for DFF 13. LF oscillator 12 generates a low frequency oscillating signal 15, which provides a clock signal for DFF 13. Thus, DFF 13 samples high frequency oscillating signal 14 at a low frequency determined by clock signal 15 and outputs a sequence of bit steam 16. If the frequency of the LF oscillator randomly drifts with each cycle (jitter), then output bit stream 16 would be random.

In the example of FIG. 1, LF oscillator 12 is a ring oscillator comprising a number of inverting stages. For example, each inverting stage is formed by an inverter comprising a P-channel field effect transistor (PFET) and an N-channel field effect transistor (NFET). Due to thermal noise present in the transistors, clock signal 15 has some jitter and its frequency randomly drifts from cycle to cycle. Such jitter causes the drift of phase relationship between HF oscillator 11 and LF oscillator 12, which in turn provides some random behavior of output bit stream 16. It has been reported, however, that sufficient randomness cannot be achieved under this technique. Improvement is sought to achieve better results.

### SUMMARY

A random number generator comprises a first high frequency (HF) oscillator, a second low frequency (LF) oscillator, a delay buffer, a multiplexer, and a sampling circuit. A first high frequency oscillating signal is generated by the HF oscillator. A second low frequency oscillating signal is generated by the LF oscillator comprising a plurality of inverting stages. The second LF oscillating signal has a jitter distribution due to random thermal noise present in the CMOS transistors in each of the inverting gate of the LF oscillator. The multiplexer selects from the second LF oscillating signal and a delayed version of the second LF oscillating signal to generate a third oscillating signal. As a result, the jitter distribution of the second LF oscillating signal is increased to a larger jitter distribution of the third oscillating signal. The third oscillating signal is then used to sample the HF oscillating signal to output a sequence of random bit stream. The increased jitter of the third oscillating signal increases the randomness of the output bit stream.

In one embodiment, a delay buffer is used to generate the delayed version of the second LF oscillating signal with a delay time D. The delay time D provided by the delay buffer is then randomly multiplexed in and out by the multiplexer to generate the third oscillating signal. In addition, the random bit stream is feedback to the multiplexer to make the randomized multiplexing. By randomly multiplexing the time delay to the third oscillating signal, the original jitter distribution of the second LF oscillating signal is “smeared” or “stretched” to a larger jitter distribution of the third oscillating signal over a wider window of time. By using the random bit stream to make the randomized multiplexing, the resulting increase in jitter has a large-grained pseudo-random behavior superimposed upon a smaller true random behavior.

Other embodiments and advantages are described in the detailed description below. This summary does not purport to define the invention. The invention is defined by the claims.

### BRIEF DESCRIPTION OF THE DRAWINGS

The accompanying drawings, where like numerals indicate like components, illustrate embodiments of the invention.

FIG. 1 (Prior Art) illustrates a conventional random number generator.

FIG. 2 is a simplified block diagram of a first embodiment of a random number generator in accordance with one novel aspect.

FIG. 3 illustrates waveform diagrams of a random number generator in accordance with one novel aspect.

FIG. 4 is a diagram that illustrates jitter distribution of an oscillating signal in FIG. 2.

FIG. 5 is a diagram that illustrates simulation result of jitter distribution in accordance with one novel aspect.

FIG. 6 is a flow chart of a method of increasing jitter distribution within a random number generator in accordance of one novel aspect.

FIG. 7 is a simplified block diagram of a second embodiment of a random number generator in accordance with one novel aspect.

FIG. 8 is a diagram that illustrates jitter distribution of an oscillating signal in FIG. 7.

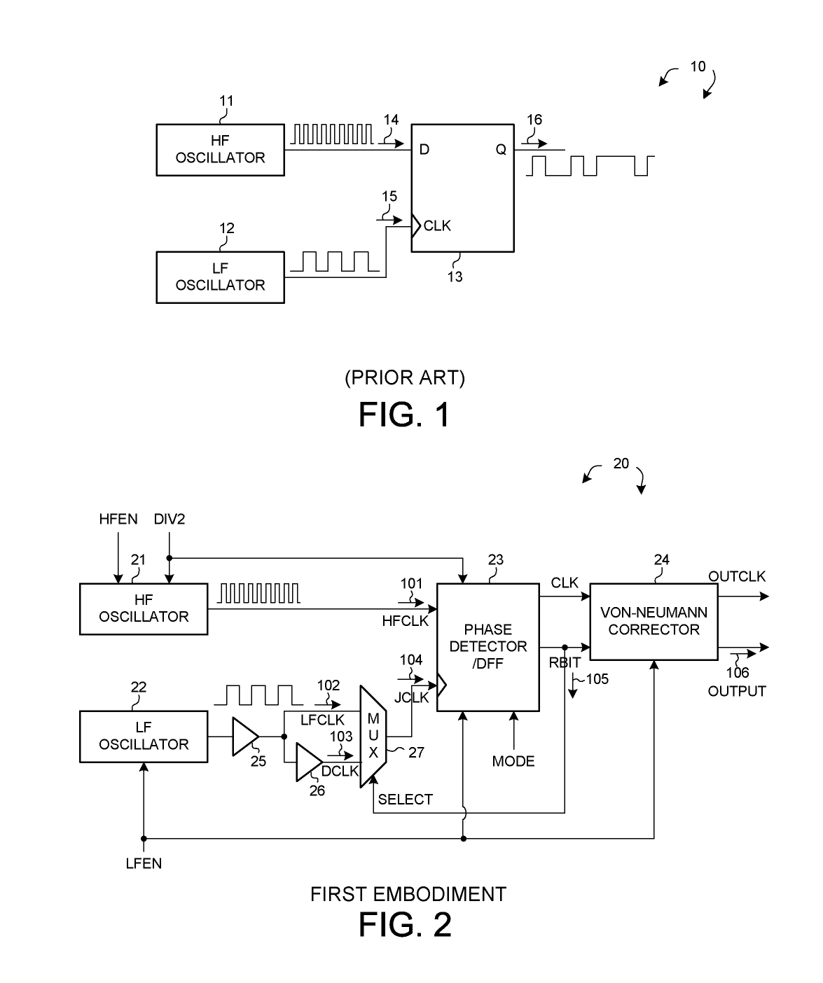

### DETAILED DESCRIPTION

Reference will now be made in detail to some embodiments of the invention, examples of which are illustrated in the accompanying drawings.

FIG. 2 is a simplified block diagram of a first embodiment of a random number generator 20 in accordance with one novel aspect. Random number generator 20 comprises a high frequency (HF) oscillator 21, a low frequency (LF) oscillator 22, a phase detector (PD) or D-type flip-flop (DFF) 23, a Von-Neumann corrector 24, delay buffers 25 and 26, and a multiplexer 27. HF oscillator 21 receives an enable signal HFEN that enables the HF oscillator to generate a high frequency oscillating signal HFCLK 101. LF oscillator 22 receives another enable signal LFEN that enables the LF oscillator to generate a low frequency oscillating signal LFCLK 102. Enable signal LFEN also controls the enabling/disabling of PD/DFF 23 and Von-Neumann corrector 24. Multiplexer 27 selects from LFCLK 102 and DCLK 103 (e.g., a delayed version of LFCLK 102), and outputs a jitter clock signal JCLK 104. PD/DFF 23 samples HFCLK 101 using JCLK 104 and outputs a random bit stream RBIT 105. PD/DFF 23 is controlled by a mode signal MODE to switch between a phase detector and a D-type flip-flop. In addition, a divide-by-two control signal DIV2 is optionally used to reduce the high frequency oscillating speed of HFCLK 101 should radio frequency noise interfere with unrelated radio. Ideally, RBIT 105 is a random bit stream having truly randomized digital values of LOW (“0”) or HIGH (“1”). To balance the number of LOWs and HIGHs, RBIT 105 is supplied onto Von-Neumann corrector 24, which generates an output bit stream OUTPUT 106 and an output clock signal OUTCLK. Von-Neumann corrector 24 outputs the final random bit stream OUTPUT 106 by removing all 0/1 biases in random bit stream RBIT 105.

It is well known in the art that timing jitter found in CMOS ring oscillators can be used as a source of true randomness. Timing jitter is a stochastic phenomenon caused by channel thermal noise present in the transistors of a ring oscillator. In the example of FIG. 2, for instance, LF oscillator 22 is a ring oscillator comprising a plurality of inverting stages. Each inverting stage is formed by an inverter comprising a pair of P-channel and N-channel transistors. Due to the thermal noise present in each of the transistors in each inverter, the oscillating period of LFCLK 102 drifts randomly from cycle to cycle resulting in a jitter distribution of the oscillating frequency of LFCLK 102. Because JCLK 104 is a multiplexed version based on LFCLK 102 and DCLK 103, JCLK 104 also has a jitter distribution. As a result, the timing jitter of JCLK 104 causes the phase relation between HFCLK 101 and JCLK 104 to drift randomly, resulting in a random bit stream RBIT 105.

In general, the randomness of RBIT 105 depends on the jitter distribution of JCLK 104. To ensure true random behavior of RBIT 105, the jitter distribution of JCLK 104 is expected to be large compared to the period of the HF oscillating signal HFCLK 101. Ideally, the jitter distribution of JCLK 104 is expected to be at least 1.5 times the oscillating period of HFCLK 101. For example, if the oscillating frequency of HFCLK is 5 GHz, then the jitter distribution of JCLK 104 should be more than 300 ps. In one novel aspect, the jitter distribution of JCLK 104 is increased to a desirable value via the use of delay buffer 26 and multiplexer 27. As illustrated below with more details, a time delay D provided by delay buffer 26 is randomly multiplexed in and out by multiplexer 27 via random bit stream RBIT 105 such that the jitter distribution of JCLK 104 is largely increased.

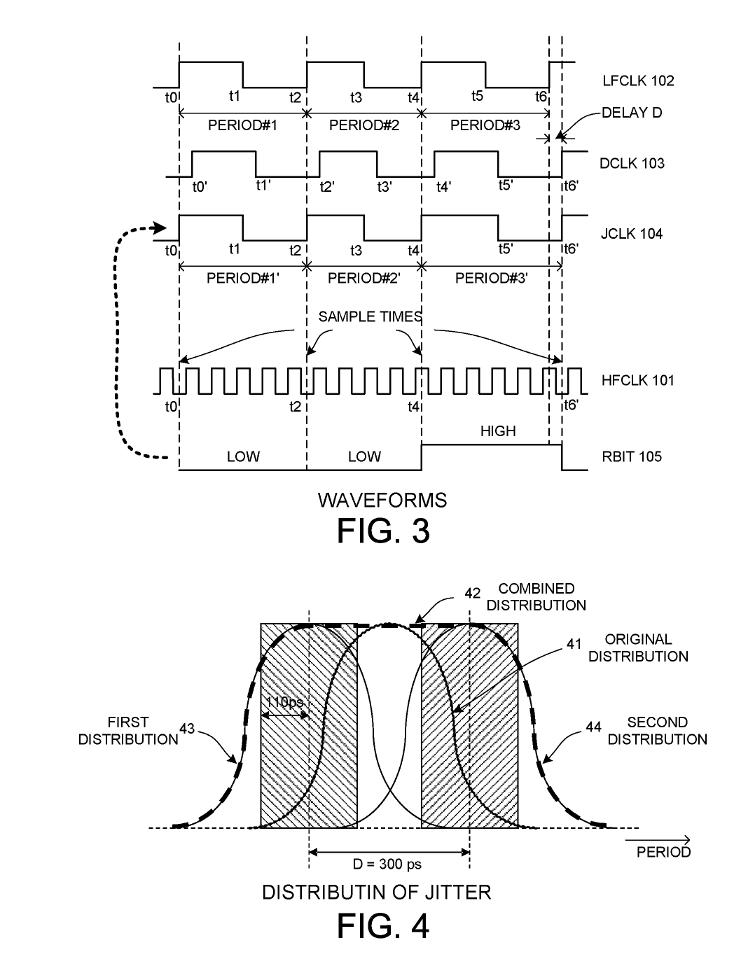

FIG. 3 illustrates waveform diagrams of random number generator 20 in FIG. 2 in accordance with one novel aspect. As illustrated in FIG. 3, LF ring oscillator 22 generates oscillating signal LFCLK 102 having rising edges at time instants t0, t2, t4, t6 and falling edges at time instants t1, t3, t5. Due to thermal noise, the oscillating period of LFCLK 102 drifts from cycle to cycle resulting in a jitter distribution. For example, a first oscillating period#1=t2−t0 is different from a second oscillating period#2=t4−t2. Similarly, the oscillating period of delay clock DCLK 103, which is a delayed version of LFCLK 102 (with delay time D), also drifts from cycle to cycle exactly the same way as LFCLK 102, and thus resulting in the same jitter distribution as LFCLK 102. On the other hand, the oscillating period of jitter clock JCLK 104, which is a multiplexed version based on LFCLK 102 and DCLK 103, drifts from cycle to cycle differently. The actual waveform of JCLK 104 depends on the value of RBIT 105, which is used as the SELECT signal by multiplexer 27.

In the example of FIG. 3, LFCLK 102 is selected by multiplexer 27 when the value of RBIT 105 is LOW, and DCLK 103 is selected by multiplexer 27 when the value of RBIT 105 is HIGH. Therefore, the first two oscillating cycle of JCLK 104 is the same as LFCLK 102 because the value of RBIT 105 is LOW. The third oscillating cycle of JCLK 104, on the other hand, follows DCLK 103 because the value of RBIT 105 is HIGH. As a result, period#1′ and period#2′ of JCLK 104 is the same as period#1 and period#2 of LFCLK 102 respectively (i.e., period#1′=t2−t0, period#2′=t4−t2), while period#3′ of JCLK 104 is longer than period#3 of LFCLK 102 by a delay time D provided by delay buffer 26 (i.e., period#3′=t6′−t4, period#3=t6−t4, and t6′−t6=delay D). It can be seen that, in addition to the original drift caused by thermal noise, the oscillating period of JCLK 104 drifts even more because the delay time D is randomly introduced onto JCLK 104.

To generate random bit stream RBIT 105, each low-to-high rising edge (or alternatively, each high-to-low falling edge) of JCLK 104 is used to sample a much higher frequency oscillating signal HFCLK 101 generated by HF oscillator 21. For example, HFCLK 101 is sampled at various transition time instants t0, t2, t4, and t6′. At time t0, the sampled value of HFCLK 101 is a digital LOW (“0”); at time t2, the sampled value of HFCLK 101 is also a digital LOW (“0”); at time t4, the sampled value of HFCLK 101 is a digital HIGH (“1”); and at time t6′, the sampled value of HFCLK 101 is a digital LOW (“0”). Therefore, the timing jitter of JCLK 104 causes the phase relation between HFCLK 101 and JCLK 104 to drift randomly, resulting in a random bit stream RBIT 105. At the meantime, because the RBIT 105 is also used to randomly switch in and out the time delay D provided by buffer 26, the jitter distribution of JCLK 104 is further increased to ensure true random behavior of RBIT 105.

FIG. 4 is a diagram that illustrates the jitter distributions of LFCLK 102 and JCLK 104 in FIG. 2. As illustrated in FIG. 4, the period of LFCLK 102 has an original jitter distribution curve 41, and the period of JCLK 104 has a combined distribution curve 42 in thick dashed line. The combined distribution curve 42 is formed by combing a first distribution curve 43 and a second distribution curve 44, each separated by a delay time D=300 ps. This is because when delay time D=300 ps from delay buffer 26 is randomly introduced onto JCLK 104, some of the JCLK cycles follows LFCLK 102, and some of the JCLK cycles follow DLCK 103, in a random fashion. By multiplexing the time delay D=300 ps to JCLK 104, the jitter distribution of JCLK 104 is separated into two distribution curves 43 and 44. As a result, the original jitter distribution of LFCLK 102 (e.g., jitter=110 ps) is “smeared” or “stretched” to a larger jitter distribution of JCLK 104 (e.g., jitter=240 ps) over a wider window of time. By using random bit stream RBIT 105 to make randomized selection between LFCLK 102 and DCLK 103, the resulting increase in jitter has a large-grained pseudo-random behavior superimposed upon a smaller true random behavior.

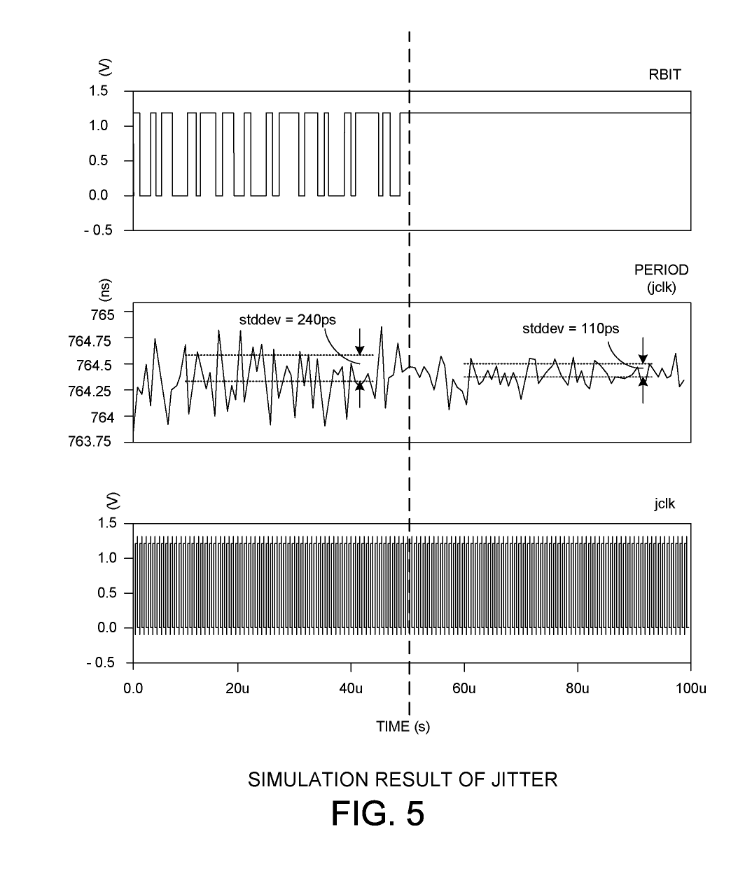

FIG. 5 is a diagram that illustrates simulation result of jitter distribution in accordance with one novel aspect. The top part of FIG. 5 is the waveform of a random bit stream RBIT. The bottom part of FIG. 5 is the waveform of a jitter clock signal JCLK that is selected from an LF oscillating signal and a delayed version of the LF oscillating signal based on the random bit stream RBIT. The middle part of FIG. 5 is the measurement of each individual PERIOD corresponding to each oscillating cycle of JCLK. Based on the PERIOD measurement values of JCLK, the jitter distribution of JCLK can be derived by calculating the standard deviation of PERIOD. As illustrated in FIG. 5, the randomness of random bit stream RBIT can be configured during the simulation process. During time 50 μs to 100 μs (the right part of FIG. 5 from the dashed line), RBIT is configured to have a constant HIGH (“1”) digital value. JCLK is then always equivalent to the original LF oscillating signal. The standard deviation of the PERIOD of JCLK under this scenario is equal to 110 ps. On the other hand, during time 0.0 to 50 μs (the left part of FIG. 5 up to the dashed line), RBIT is configured to be a random bit stream having random HIGHS and LOWS. JCLK is then randomly selected from the LF oscillating signal and its delayed version (with D=300 ps). As a result, the standard deviation of the PERIOD of JCLK reaches 240 ps.

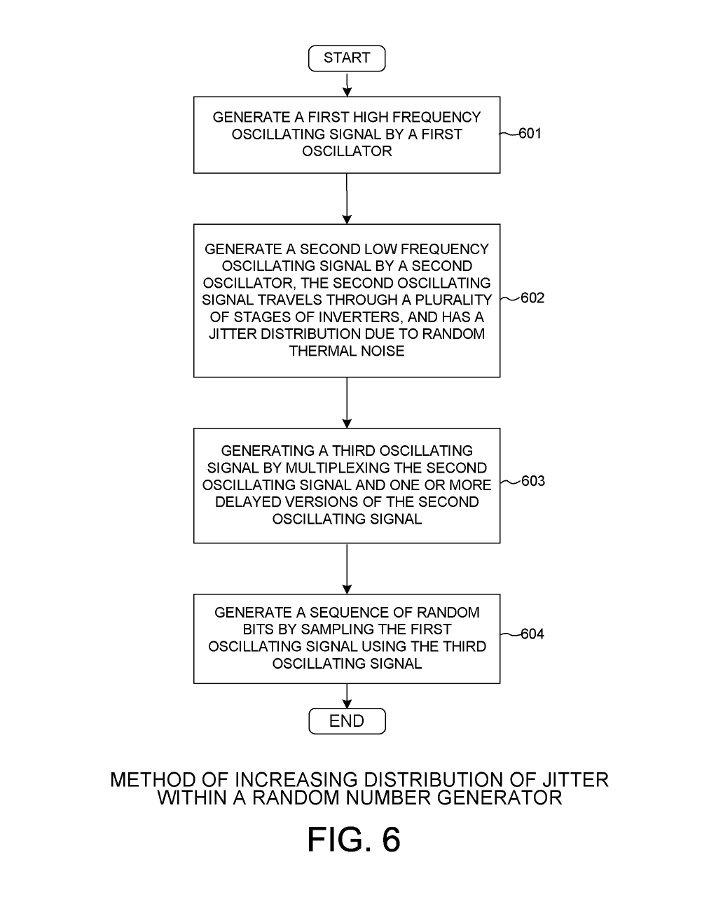

FIG. 6 is a flow chart of a method of increasing jitter distribution within a random number generator in accordance of one novel aspect. In step 601, a first high frequency (HF) oscillating signal is generated by a first HF ring oscillator. In step 602, a second low frequency (LF) oscillating signal is generated by a second LF ring oscillator comprising a plurality of inverting stages. The second LF oscillating signal has a jitter distribution due to random thermal noise present in the CMOS transistors in each of the inverting gate of the LF ring oscillator. In step 603, a third oscillating signal is generated by multiplexing the second LF oscillating signal and one or more delayed versions of the second LF oscillating signal. As a result, the original jitter distribution of the second LF oscillating signal is increased to a larger jitter distribution of the third oscillating signal. Finally, in step 604, the third oscillating signal is used to sample the first HF oscillating signal to output a sequence of random bit stream. The increased jitter of the third oscillating signal ensures sufficient randomness of the output bit stream.

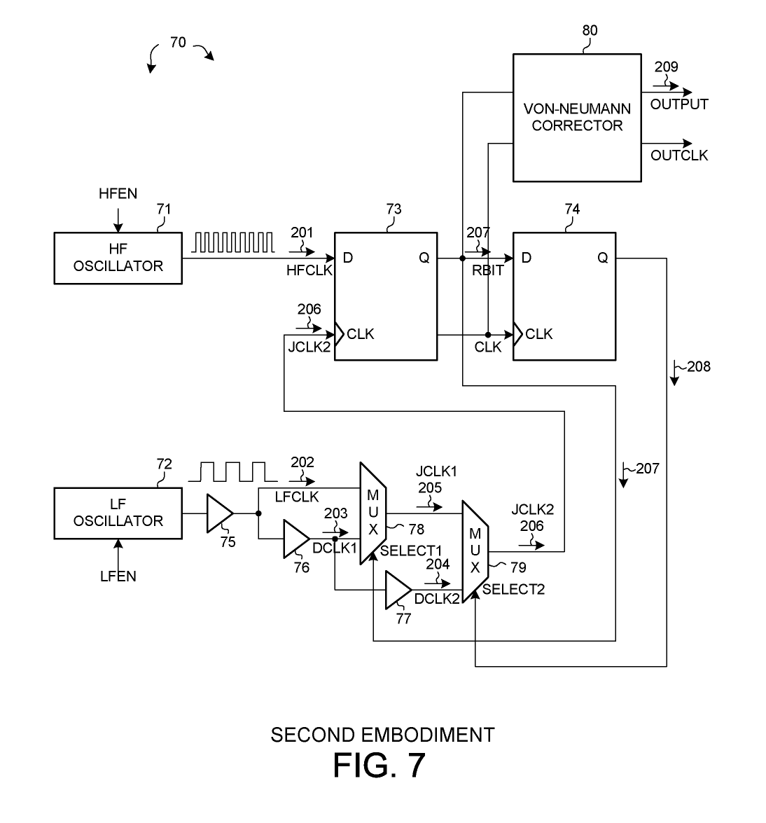

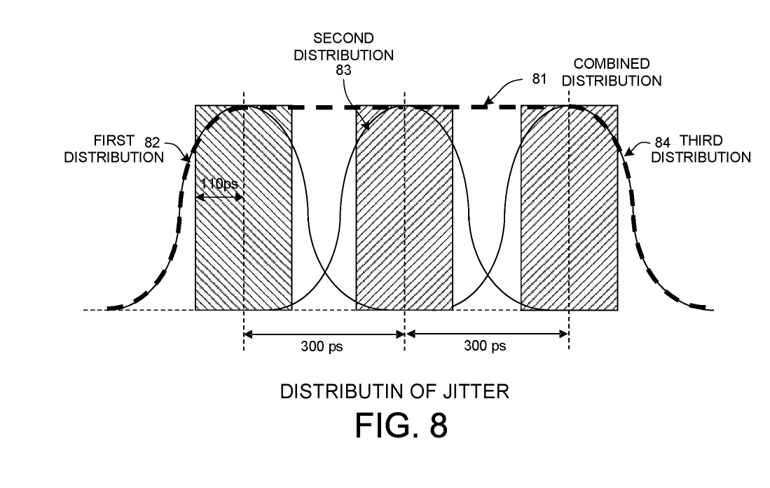

FIG. 7 is a simplified block diagram of a second embodiment of a random number generator 70 in accordance with one novel aspect. Random number generator 70 comprises a high frequency (HF) oscillator 71, a low frequency (LF) oscillator 72, a first D-type flip-flop (DFF) 73, a second DFF 74, delay buffers 75-77, a first multiplexer 78, a second multiplexer 79, and a Von-Neumann corrector 80. HF oscillator 71 receives an enable signal HFEN that enables the HF oscillator to generate a high frequency oscillating signal HFCLK 201. LF oscillator 72 receives another enable signal LFEN that enables the LF oscillator to generate a low frequency oscillating signal LFCLK 202. LFCLK 202 is supplied onto delay buffer 76 that outputs DCLK1 203, which is a first delayed version of LFCLK 202. DCLK1 203 is further supplied onto delay buffer 77 that outputs DCLK2 204, which is a second delayed version of LFCLK 202. Multiplexer 78 selects between LFCLK and DCLK1 to generate a first jitter clock JCLK1 205. Multiplexer 79 selects between JCLK1 205 and DCLK2 204 to generate a second jitter clock JCLK2 206.

DFF 73 then uses the second jitter clock JCLK2 206 to sample the HF oscillating signal HFCLK 201 and outputs a random bit stream RBIT 207. RBIT 207 is used as a first selection signal (i.e., SELECT1) for multiplexer 78. In addition, RBIT 207 is also supplied onto DFF 74 to output a second selection signal 208 (i.e., SELECT2) for multiplexer 79. Ideally, RBIT 207 is a random bit stream having truly randomized digital values of LOW (“0”) or HIGH (“1”). To balance the number of LOWs and HIGHs, RBIT 207 is supplied onto Von-Neumann corrector 80, which generates an output bit stream OUTPUT 209 and an output clock signal OUTCLK. Von-Neumann corrector 80 outputs the final random bit stream OUTPUT 209 by removing all 0/1 biases in random bit stream RBIT 207.

The randomness of RBIT 207 depends on the jitter distribution of JCLK2 206, because the value of RBIT 207 varies based on the random drift of phase relationship between HFCLK 101 and JCLK2 caused by the timing jitter of JCLK2. In general, to ensure true random behavior of RBIT 207, the jitter distribution of JCLK2 206 is expected to be large compared to the period of the HF oscillating signal HFCLK 101. In one novel aspect, the jitter distribution of JCLK2 206 is increased to a desirable value via the use of delay buffers 76-77 and multiplexers 78-79. In the example of FIG. 7, a first time delay D1 provided by delay buffer 76 is randomly multiplexed in and out by multiplexer 78 via SELECT1 (i.e., random bit stream RBIT 207) such that the jitter distribution of JCLK1 205 is increased. Furthermore, a second time delay D2 provided by delay buffer 77 is randomly multiplexed in and out by multiplexer 79 via SELECT2 (i.e., a delayed version of random bit stream 207) such that the jitter distribution of JCLK2 206 is further increased.

FIG. 8 is a diagram that illustrates jitter distribution of low frequency oscillating signal JCLK2 206 depicted in FIG. 7. As illustrated in FIG. 8, the oscillating period of JCLK2 206 has a combined distribution curve 81 in thick dashed line. The combined distribution curve 81 is formed by combing a first distribution curve 82, a second distribution curve 83, and a third distribution curve 84, each of the curves are separated by a delay time D=300 ps. This is because when a first delay time D1=300 ps from delay buffer 76 is randomly introduced onto JCLK1 205, and a second delay time D2=300 ps from delay buffer 77 is randomly introduced onto JCLK2 206, on average one third of the JCLK2 cycles are reduced by 300 ps, one third of the JCLK2 cycles remain the same, and one third of the JCLK2 cycles are increased by 300 ps, in a random fashion. By multiplexing two time delays (D=D1=D2=300 ps) to JCLK1 and then to JCLK2, the jitter distribution of JCLK2 is separated into three distribution curves 82, 83 and 84. As a result, the original jitter distribution of LFCLK 202 (e.g., jitter=110 ps) is “smeared” or “stretched” to a larger jitter distribution of JCLK2 206 (e.g., jitter=390 ps) over a wider window of time. By using random bit stream SELECT1 and SELECT2 to make randomized selection between LFCLK 202 and DCLK1 203, as well as between JCLK1 205 and DCLK2 204 respectively, the resulting JCLK2 206 with increased jitter distribution has a large-grained pseudo-random behavior superimposed upon a smaller true random behavior of LFCLK 202.

It is noted that the above-described method and apparatus is only a way to stretch the magnitude of existing random jitter. Thus, the low frequency oscillator (i.e., LF oscillator 22) needs to have a source of truly random noise (i.e., channel thermal noise) to produce the random jitter that leads to good streams of random bits (i.e., RBIT 105). Without a source of truly random noise, this method and apparatus devolves into a pseudo-random source.

Although the present invention has been described in connection with certain specific embodiments for instructional purposes, the present invention is not limited thereto. Accordingly, various modifications, adaptations, and combinations of various features of the described embodiments can be practiced without departing from the scope of the invention as set forth in the claims.

What is claimed is:

1. A random number generator, comprising:
a first oscillator that outputs a first oscillating signal;
a second oscillator that outputs a second oscillating signal, wherein the second oscillating signal has a much lower frequency than the first oscillating signal; and
a sampling circuit that samples the high frequency oscillating signal using a third oscillating signal, and in response generates a sequence of random bits, wherein the third oscillating signal is selected from the second oscillating signal and one or more delayed versions of the second oscillating signal.

2. The random number generator of claim 1, wherein the third oscillating signal is selected based on the sequence of random bits.

3. The random number generator of claim 2, further comprising:
a delay buffer that receives the second oscillating signal and outputs a delayed version of the second oscillating signal; and
a selection circuit that selects from the second oscillating signal and the delayed version of the second oscillating signal based on the sequence of random bits.

4. The random generator of claim 3, wherein the second oscillating signal has a jitter distribution due to thermal noise, and wherein the thermal noise is a true random source.

5. The random number generator of claim 4, wherein the delay buffer and the selection circuit are used such that the third oscillating signal has a larger jitter distribution than the second oscillating signal.

6. The random number generator of claim 4, wherein multiple delay buffers and multiplexers are used such that the third oscillating signal has a larger jitter distribution than the second oscillating signal.

7. The random number generator of claim 1, wherein the sampling circuitry is either a phase detector or a D-type Flip-Flop.

8. The random number generator of claim 1, wherein the sampling circuit further comprises a corrector for assuring the sequence of random bits has approximately equal number of zeros and ones on average.

9. A method for generating a sequence of random bits, comprising:
generating a first high frequency oscillating signal by a first oscillator;
generating a second low frequency oscillating signal by a second oscillator;
generating a third oscillating signal by selecting from the second oscillating signal and one or more delayed versions of the second oscillating signal; and
generating a sequence of random bits by sampling the first oscillating signal using the third oscillating signal.

10. The method of claim 9, wherein the third oscillating signal is selected based on the sequence of random bits.

11. The method of claim 10, wherein the generating of the third oscillating signal further comprises:
receiving the second oscillating signal by a delay buffer and in response outputting a delayed version of the second oscillating signal; and
selecting from the second oscillating signal and the delayed version of the second oscillating signal by a selection circuit based on the sequence of random bits.

12. The method of claim 11, wherein the second oscillating signal has a jitter distribution due to thermal noise, and wherein the thermal noise is a true random source.

13. The method of claim 12, wherein the delay buffer and the multiplexer are used such that the third oscillating signal has a larger jitter distribution than the second oscillating signal.

14. The method of claim 12, wherein multiple delay buffers and multiplexers are used such that the third oscillating signal has a larger jitter distribution than the second oscillating signal.

15. The method of claim 9, wherein the sampling circuit is either a phase detector or a D-type Flip-Flop.

16. The method of claim 9, wherein the sequence of random bits is corrected to have approximately equal number of zeros and ones on average.

17. An oscillator, comprising:
a ring oscillator that generates a first oscillating signal;
a delay buffer that receives the first oscillating signal and outputs a delayed version of the first oscillating signal; and
a selection circuit that outputs a second oscillating signal by selecting from the first oscillating signal and the delayed version of the first oscillating signal based on a sequence of random bits, wherein a jitter distribution of the second oscillating signal is larger than a jitter distribution of the first oscillating signal.

18. The oscillator of claim 17, wherein the ring oscillator comprises a plurality of inverters, each inverter comprises a number of transistors.

19. The oscillator of claim 18, wherein the first oscillating signal has the jitter distribution due to thermal noise present in the transistors of the ring oscillator, and wherein the thermal noise is a true random source.

20. The oscillator of claim 17, wherein the second oscillating signal is used to sample a high frequency oscillating signal to generate the sequence of random bits.
